(19) United States
(12) Patent Application Publication
(10) Pub. No.: US 2009/0212356 A1
(43) Pub. Date: Aug. 27, 2009

(54) SEMICONDUCTOR DEVICE

(75) Inventor: Atsushi YAMADA, Nagoya-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/366,210

(22) Filed: Feb. 5, 2009

(30) Foreign Application Priority Data
Feb. 21, 2008 (JP) 2008-039763

(51) Int. Cl. H01L 29/78

(52) U.S. Cl. 257/328; 257/E29.257

(57) ABSTRACT

A semiconductor device includes: a double-diffused metal oxide semiconductor (DMOS) transistor having a gate electrode and a drain electrode region; and a protection element protecting the gate electrode with respect to overvoltage and coupled to the DMOS transistor on a structure of one semiconductor substrate. The DMOS transistor and the protection element are included in an element integrated structure. In the device, the protection element is formed on a diffusion region, which is separately formed with respect to a diffusion region for the DMOS transistor, in the drain electrode region of the DMOS transistor.

The entire disclosure of Japanese Patent Application No. 2008-39763, filed Feb. 21, 2008 is expressly incorporated by reference herein.

### BACKGROUND

1. Technical Field

An aspect of the present invention relates to a semiconductor device having a structure in which a protection element for protecting a gate electrode with respect to overvoltage (surge voltage) is coupled to a double-diffused metal oxide semiconductor (DMOS) transistor (also called a power MOS transistor) on one semiconductor substrate structure as an element integrated structure.

2. Related Art

In DMOS transistors known as a high breakdown voltage large current MOS device, it is commonly preferable that a switching operation is performed with an increased withstanding-voltage of a drain electrode and a low resistance. Therefore, it seems to be preferable that the film thickness of a gate electrode is decreased as thin as possible so as to improve a current amplification factor β.

However, if the film thickness of the gate electrode is thinned, an electrical intensity applied to the film is increased so as to decrease insulation-breakdown voltage of the gate electrode, in practice. Consequently, the device (the DMOS transistor) is broken when overvoltage is applied. Especially, in a case where the device is applied as a switching element of an H-bridge type circuit, for example, for driving a motor, the device is easily broken down when a high surge voltage generated in switching the DMOS transistor from On to Off is applied from the drain electrode to the gate electrode through a parasitic capacitance Cgd present between the drain electrode and the gate electrode.

Therefore, a protection element typified by a zener diode or an NPN type transistor is used so as to protect the gate electrode with respect to an application of overvoltage as above. JP-A-9-129762 (summary and FIG. 1), for example, discloses a semiconductor device in which a zener diode serving as the protection element for protecting the gate electrode of the DMOS transistor is provided on one semiconductor substrate structure.

In a case of a structure in which the protection element for protecting the gate electrode of the DMOS transistor is coupled to the DMOS transistor on one semiconductor substrate structure in the semiconductor device of the above example, an element region for forming the DMOS transistor and an element region for forming the protection element are element-isolated by an element isolation region so as to be formed separately. Therefore, a large occupation area for securing the element regions and the element isolation regions is required on one chip. Thus, the chip area can not be reduced disadvantageously.

FIG. 4 illustrates a basic structure of a related art semiconductor device by a side cross section of a semiconductor substrate structure. FIG. 4 shows a P-type semiconductor substrate 10 (so called, a P-type substrate) that is common and has an epitaxial layer 11 on its surface, as one semiconductor substrate. A first P-type diffusion region for forming a DMOS transistor 1 is formed in a first N-type region N− of an epitaxial layer 11. The first P-type diffusion region N− is formed by being surrounded by a first N-type embedded region BN(N+), first N-type embedded regions N(PLG), and first N-type diffusion regions N+ (coupled to a drain electrode D of the DMOS transistor 1). The first N-type embedded region BN(N+) is embedded at a boundary part between the epitaxial layer 11 and the P-type semiconductor substrate 10. The first N-type embedded regions N(PLG) are embedded on end parts of the first N-type embedded region BN(N+) with a predetermined distance to each other at the boundary part. The first N-type diffusion regions N+ are formed on the first N-type embedded regions N(PLG) in a manner exposing their surfaces from the epitaxial layer 11.

Further, on the P-type semiconductor substrate 10, P-type embedded regions BP, P-type embedded regions P(PLG), and P-type diffusion regions P+ (coupled to the ground so as to receive a ground voltage) are provided. The P-type embedded regions BP are embedded at the boundary part between the epitaxial layer 11 and the P-type semiconductor substrate 10 with a predetermined distance to each other in a manner sandwiching the first N-type embedded region BN(N+). The P-type embedded regions P(PLG) are embedded on the P-type embedded regions BP. The P-type diffusion regions P+ are formed on the P-type embedded regions P(PLG) in a manner exposing their surfaces from the epitaxial layer 11.

Consequently, a region surrounded by the first N-type embedded region BN(N+), the first N-type embedded regions N(PLG), and the first N-type diffusion regions N+ is an element region E2 for forming the DMOS transistor 1, and a region including the P-type embedded region BP, the P-type embedded region P(PLG), and the P-type diffusion region P+ is an element isolation region E1.

A second P-type diffusion region for forming a diode 2 serving as the protection element is formed in a second N-type region N− of the epitaxial layer 11. The second N-type region N− is formed by being surrounded by a second N-type embedded region BN(N+), second N-type embedded regions N(PLG), and second N-type diffusion regions N+. The second N-type embedded region BN(N+) is embedded at the boundary part between the epitaxial layer 11 and the P-type semiconductor substrate 10. The second N-type embedded regions N(PLG) are embedded on end parts of the second N-type embedded region BN(N+) at the boundary part with a predetermined distance to each other. The second N-type diffusion regions N+ for forming an electrode are formed on the second N-type embedded regions N(PLG) in a manner exposing their surfaces from the epitaxial layer 11.

Further, on the P-type semiconductor substrate 10 provided with the epitaxial layer 11, P-type embedded regions BP, P-type embedded regions P(PLG), and P-type diffusion regions P+ (coupled to the ground so as to receive a ground voltage) are provided. The P-type embedded regions BP are embedded at the boundary part between the epitaxial layer 11 and the P-type semiconductor substrate 10 in a manner sandwiching the second N-type embedded region BN(N+) at a distance. The P-type embedded regions P(PLG) are embedded on the P-type embedded regions BP. The P-type diffusion regions P+ are formed on the P-type embedded regions P(PLG) in a manner exposing their surfaces from the epitaxial layer 11.

Consequently, a region surrounded by the second N-type embedded region BN(N+), the second N-type embedded regions N(PLG), and the second N-type diffusion regions N+ is an element region E2 for forming the diode 2, and a region including the P-type embedded region BP, the P-type embedded region P(PLG), and the P-type diffusion region is an element isolation region E1.

As a whole, the semiconductor substrate structure needs two N-type embedded regions BN(N+), four N-type embedded regions N(PLG) formed on the N-type embedded regions BN(N+), and four N-type diffusion regions N+ so as to secure the two element regions E2, and also needs three P-type embedded regions BP, three P-type embedded regions P(PLG), and three P-type diffusion regions P so as to secure the element isolation regions E1 sandwiching the two element regions E2, thereby requiring a large occupation area on one chip.

### SUMMARY

An advantage of the present invention is to provide a high-performance semiconductor device having a structure in which a protection element is coupled to a DMOS transistor on one semiconductor substrate, having a small one-chip size, and being realized at a low cost.

A semiconductor device according to an aspect of the invention includes: a double-diffused metal oxide semiconductor (DMOS) transistor (a DMOS transistor 1 in FIG. 1, for example) having a gate electrode and a drain electrode region; and a protection element (a zener diode 2 in FIG. 1, for example) protecting the gate electrode with respect to overvoltage and coupled to the DMOS transistor on a structure of one semiconductor substrate. The DMOS transistor and the protection element are included in an element integrated structure. In the device, the protection element is formed on a diffusion region (a P-type diffusion region for forming the zener diode 2 in FIG. 1, for example), which is separately formed with respect to a diffusion region for the DMOS transistor, in the drain electrode region [for example, an N-type region N−, which is shown in FIG. 1, formed by being surrounded by an N-type embedded region BN(N+), the N-type embedded region BN(N+) being embedded at a boundary part between an epitaxial layer 11 that is coupled to a terminal for a drain electrode D; N-type embedded regions N(PLG), the N-type embedded regions N(PLG) being embedded on end parts of the N-type embedded region BN(N+) at the boundary part with a predetermined distance from each other; and N-type diffusion regions N+, the N-type diffusion regions N+ being formed on the N-type embedded regions N(PLG) to expose surfaces thereof from the epitaxial layer 11 and being coupled to the drain electrode D, in an element region E2] of the DMOS transistor.

As above, the semiconductor device has the element integrated structure in which the DMOS transistor and the protection element are integrated in one element region (an element region E2 in FIG. 1, for example). Thus the semiconductor device has the element region as small as possible in number so as to have a small occupation area (an area including not only the element region but also element isolation regions).

That is, according to the invention, a semiconductor device that has a small chip size and is realized at a low cost can be provided.

In the semiconductor device of the aspect, the one semiconductor substrate may be a P-type substrate (a P-type semiconductor substrate 10 in FIG. 1, for example) having an epitaxial layer (the epitaxial layer 11 in FIG. 1, for example) on a surface thereof. In the device, the diffusion regions that are separately formed may be P-type diffusion regions that are disposed in an N-type region of the epitaxial layer. The N-type region is formed by being surrounded by: a first N-type embedded region (the N-type embedded region BN(N+) in FIG. 1, for example), which is embedded at a boundary part between the epitaxial layer and the P-type substrate; second N-type embedded regions (the N-type embedded regions N(PLG) in FIG. 1, for example), which are embedded on end parts of the first N-type embedded region at the boundary part with a predetermined distance from each other; and N-type diffusion regions, which are formed on the second N-type embedded regions in a manner exposing surfaces thereof from the epitaxial layer. Further, in the device, the P-type diffusion regions may be a first P-type diffusion region on which the DMOS transistor is formed and a second P-type diffusion region on which the protection element is formed at a distance from the first P-type diffusion region.

Due to such structure, the DMOS transistor and the protection element can be easily formed on the P-type diffusion regions having different concentrations from each other (may have the same concentration) only by using an element forming technique with respect to the P-type semiconductor substrate including a common epitaxial layer.

In the semiconductor device of the aspect, the drain electrode region of the DMOS transistor may be element-isolated by: first P-type embedded regions (P-type embedded regions BP in FIG. 1, for example), which are embedded at the boundary part between the epitaxial layer and the P-type substrate in a manner sandwiching the first N-type embedded region; second P-type embedded regions (P-type embedded regions P(PLG) in FIG. 1, for example), which are embedded on the first P-type embedded regions; and P-type diffusion regions, which are formed on the second P-type embedded regions in a manner exposing surfaces thereof from the epitaxial layer.

Thus, such structure needs the element isolation regions (element isolation regions E1 positioned at the both sides of the element region E2 in FIG. 1, for example) only at the periphery of one element region (the element region E2 in FIG. 1, for example). Therefore, the semiconductor device of this case has the element region and the element isolation regions as small as possible in number and thus has a small occupation area. Accordingly, a high performance semiconductor device having a small chip size and realized at a low cost can be provided.

In the semiconductor device of the aspect, the one semiconductor substrate may be a P-type substrate having a triple well structure in which a P-well region is formed in an N-well region, and the P-well region may include a first P-type well region for forming the DMOS transistor and a second P-type well region for forming the protection element. In the device, the diffusion regions that are separately formed may be the first P-type well region and the second P-type well region.

In such structure as well, the DMOS transistor and the protection element can be easily formed on the P-well regions having different concentrations from each other (may have the same concentration) only by using an element forming technique with respect to the P-type semiconductor substrate having the triple well structure. In this case, the device does not have the N-type embedded region BN(N+), the N-type embedded region N(PLG), the P-type embedded region BP, and the P-type embedded region P(PLG), being able to further reduce the one chip size.

In the semiconductor device of the aspect, the DMOS transistor may be an N-type DMOS transistor (a DMOS transistor 1 in FIG. 2, for example) In the device, the protection element may be a zener diode (a zener diode 2 in FIG. 2, for example) of which an anode electrode is coupled to a source electrode of the N-type DMOS transistor and a cathode electrode is coupled to the gate electrode of the N-type DMOS transistor.

Accordingly, such a semiconductor device can be provided that has a simple structure and includes the N-type DMOS transistor and the protection element having a gate electrode film protection function in one element region (the element region E2 in FIG. 1, for example) with the P-type semiconductor substrate including a common epitaxial layer or the P-type semiconductor substrate having the triple well structure.

In the semiconductor device of the aspect, the DMOS transistor may be an N-type DMOS transistor (a DMOS transistor 1 in FIG. 3, for example). In the device, the protection element may be an NPN junction type transistor (an NPN junction type transistor 3 in FIG. 3, for example) of which an anode electrode is coupled to a source electrode of the N-type DMOS transistor and a cathode electrode is coupled to the gate electrode of the N-type DMOS transistor.

Accordingly, such a different type of semiconductor device can be provided that has a simple structure and includes the N-type DMOS transistor and the protection element having a gate electrode film protection function in one element region (the element region E2 in FIG. 1, for example) with the P-type semiconductor substrate including a common epitaxial layer or the P-type semiconductor substrate having the triple well structure.

In the semiconductor device of the aspect, the element integrated structure may be arranged side by side in a predetermined number, and the predetermined number of element integrated structures may include one of the zener diode (the zener diode 2 in FIG. 2, for example) and the NPN junction type transistor (the NPN junction type transistor 3 in FIG. 3, for example) coupled to the gate electrode and the source electrode of the N-type DMOS transistor in the drain electrode region of the N-type DMOS transistor, and may be element-isolated from each other in a manner coupling drain electrodes of the element integrated structures that are adjacent to each other and coupling source electrodes of the element integrated structures that are adjacent to each other.

Thus, a semiconductor device has a multiple structure in which the element integrated structures are arranged side by side, and the element integrated structures are isolated from each other by element isolation regions (the element isolation regions E1 in FIG. 1, for example) disposed to sandwich one element region (the element region E2 in FIG. 1, for example). In the integrated structure, the N-type DMOS transistor 1 and the protection element having a gate electrode protection function are formed. Therefore, the device has a substantially smaller size than a device having an element isolation structure of a related art, and a high-effective gate electrode protection function can be obtained. Especially, in a case where the device is applied as a switching element such as an H-bridge type circuit for driving a motor, the device does not require a large disposing space, compared to the related art, due to its element integrated structure having a substantially small size. Further, no surge voltage is applied to the gate electrode, so that the device is securely protected. Thus such device is substantially effective.

### BRIEF DESCRIPTION OF THE DRAWINGS

The invention will be described with reference to the accompanying drawings, wherein like numbers reference like elements.

FIG. 1 is a diagram illustrating a basic structure of a semiconductor device according to an embodiment by a side cross section of a semiconductor substrate structure.

FIG. 2 is a diagram illustrating an equivalent circuit of elements of the semiconductor device shown in FIG. 1.

FIG. 3 is a diagram illustrating an equivalent circuit of elements of a semiconductor device according to a first modification.

FIG. 4 is a diagram illustrating a basic structure of a related art semiconductor device by a side cross section of a semiconductor substrate structure.

### DESCRIPTION OF EXEMPLARY EMBODIMENT

A semiconductor device according to an embodiment of the invention will now be described with reference to the drawings.

### Embodiment

Structure

A structure and a function of each element will be first described.

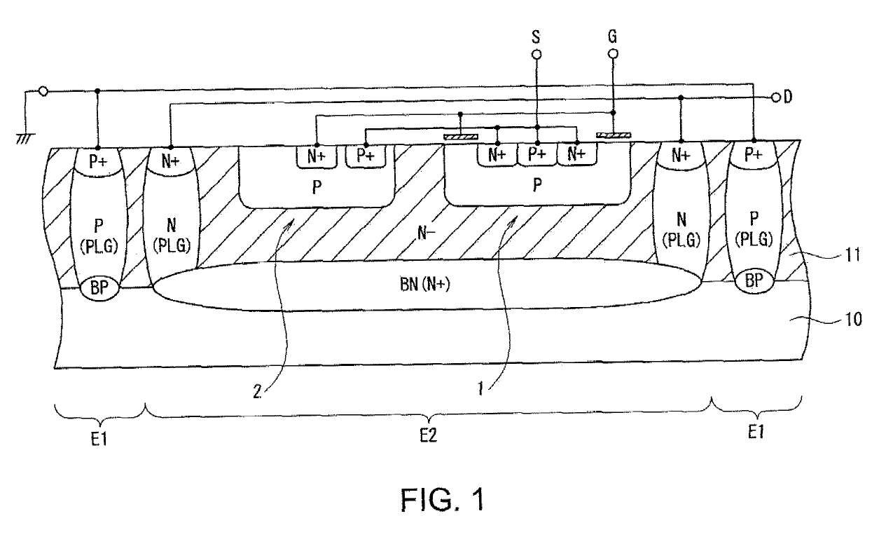

FIG. 1 illustrates a basic structure of a semiconductor device according to the embodiment by a side cross section of a semiconductor substrate structure.

This semiconductor device has an element integrated structure in which a zener diode 2 serving as a protection element is coupled to a DMOS transistor 1 in one element region E2 on one semiconductor substrate structure. The zener diode 2 protects a gate electrode from overvoltage such as surge voltage. That is, the zener diode 2 is formed on a diffusion region (a P-type diffusion region for forming the zener diode 2) that is separately formed with respect to a diffusion region for the DMOS transistor 1 in an electrode region of the DMOS transistor.

The embodiment employs a P-type semiconductor substrate 10 (so-called a P-type substrate) including an epitaxial layer 11 on its surface, as one semiconductor substrate. The diffusion regions that are separately formed are disposed at a distance at a surface side of an N-type region N− that is formed by being surrounded by an N-type embedded region BN(N+), N-type embedded regions N(PLG), and N-type diffusion regions N+ for forming an electrode. The N-type embedded region BN(N+) is embedded at a boundary part between the epitaxial layer 11 and the P-type semiconductor substrate 10 and has a large width. The N-type embedded regions N(PLG) are embedded on end parts of the N-type embedded region BN(N+) at the boundary part with a predetermined distance from each other. The N-type diffusion regions are formed on the N-type embedded regions N(PLG) so as to expose their surfaces from the epitaxial layer 11. The diffusion regions that are separately formed are a first P-type diffusion region for forming the DMOS transistor 1 and a second P-type diffusion region for forming the zener diode 2. The second diffusion region has a different concentration from (may have the same concentration as) the first diffusion region.

A drain electrode region of the DMOS transistor 1 is the N-type region N− formed by being surrounded by the N-type embedded region BN(N+) coupled to a terminal for a drain electrode D, the N-type embedded regions N(PLG), and the N-type diffusion regions N+ (coupled to the drain electrode D), in an element region E2. This drain electrode region is isolated by P-type embedded regions BP, P-type embedded regions P(PLG), and P-type diffusion regions P+. The P-type embedded regions BP are embedded at the boundary between the epitaxial layer 11 and the P-type semiconductor substrate 10 in a manner sandwiching the N-type embedded region BN(N+) at a distance. The P-type embedded regions P(PLG) are embedded on the P-type embedded regions BP. The P-type diffusion regions P+ are embedded on the P-type embedded regions P(PLG) so as to expose their surfaces from the epitaxial layer 11.

Namely, this semiconductor device only needs one N-type embedded region BN(N+), two N-type embedded regions N(PLG), and two N-type diffusion regions N(+) so as to secure one element region E2, and only needs two P-type embedded regions BP, two P-type embedded regions P(PLG), and two P-type diffusion regions P+ so as to secure element isolation regions E1 that sandwich the element region E2, thereby requiring a very small occupation area on one chip.

The DMOS transistor 1 includes a high concentration diffusion region N+ in which an electrode to be a source electrode is to be formed, and a high concentration diffusion region P+, in which an electrode to be coupled with a substrate potential is to be formed, on a surface of the first P-type diffusion region in an adjacent manner. The source electrode is coupled to a high concentration diffusion region P+ formed on a surface of the second P-type diffusion region. In the diffusion region P+, an electrode to be an anode electrode of the zener diode 2 is to be formed. The gate electrode is coupled to a high-concentration diffusion region N+ formed on a surface of the second P-type diffusion region. In the diffusion region N+, an electrode to be a cathode electrode of the zener diode 2 is to be formed.

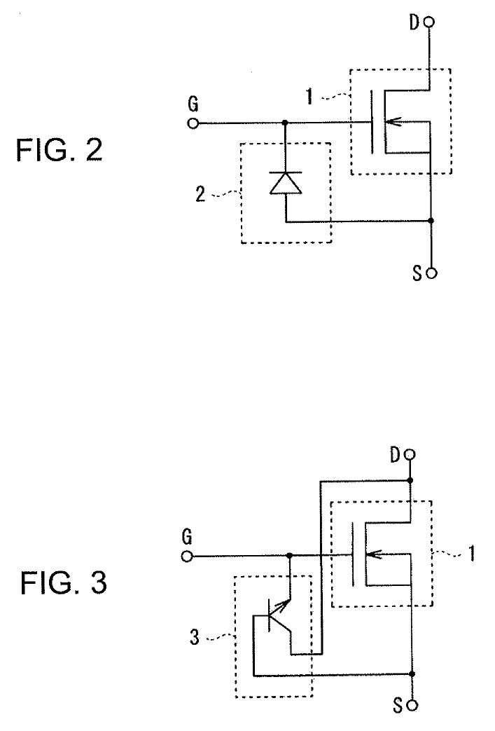

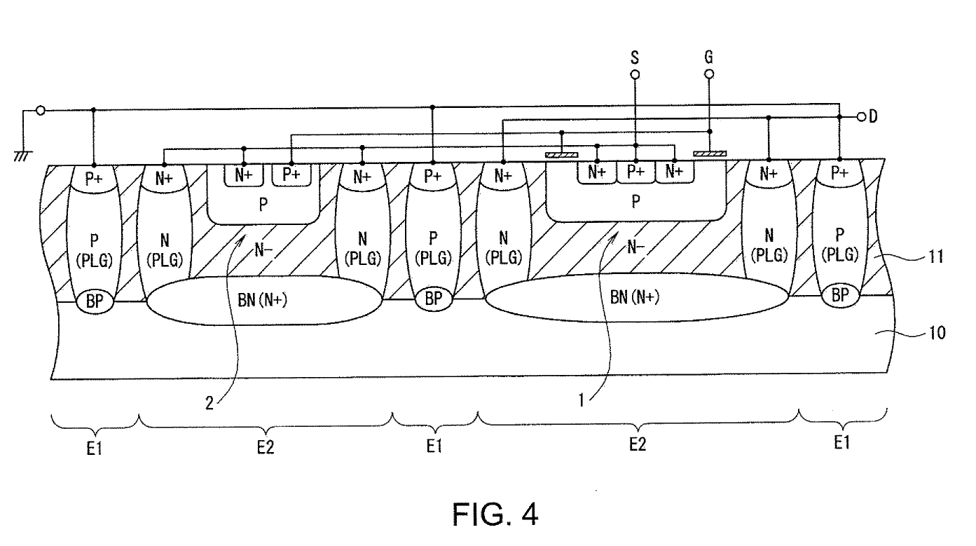

FIG. 2 illustrates an equivalent circuit of elements of the semiconductor device. Referring to FIG. 2, the elements of the semiconductor device have a circuit structure in which an anode electrode of the zener diode 2 is coupled to the source electrode of the N-type DMOS transistor 1, and the cathode electrode of the zener diode 2 is coupled to the gate electrode of the transistor 1.

Operation

An operation will now be described.

The semiconductor device of the embodiment has the element integrated structure in which the DMOS transistor 1 and the zener diode 2 are integrated on one element region E2 on one semiconductor substrate structure. The semiconductor device of the embodiment includes an N-type DMOS transistor formed together with a protection element having an electrode protection function as a related art on the equivalent circuit, and performs a switch-operation as a high withstand voltage large current MOS device.

A case where a motor driving is conducted with a high voltage supply is described here, for example. Here, a predetermined gate bias voltage is applied from the gate electrode. When the source electrode is set to be at an approximately reference voltage (ground voltage) and the switching-operation is conducted so as to allow a current to flow from the drain electrode to the source electrode, the zener diode 2 serving as the protection element stops an application of overvoltage with respect to the gate electrode even in a case where the overvoltage caused by an inductor component of a motor is generated in switching the DMOS transistor 1 from On to Off. Accordingly, the film thickness of the gate electrode can be set to be thin in advance so as to improve a current amplification factor β and thus On-operation can be conducted under increased withstand voltage in the switching operation and under a low resistance.

Here, in a case where a protection element is formed together with a common transistor of a different type, it is preferable that each element be isolated from each other as the related art in consideration of an adverse affect to the switching operation. However, the DMOS transistor 1 is used under high withstand voltage and large current flow. Therefore, even though the zener diode 2 serving as the protection element is formed close to the transistor as this case, the adverse affect is hardly imposed on the switching operation unlike the transistor of the different type so as to be able to be ignored.

As above, the semiconductor device of the embodiment has the element integrated structure in which the DMOS transistor 1 and the zener diode 2 serving as the protection element are integrated in one element region E2. Thus the semiconductor device has the element region E2 as small as possible in number so as to have a small occupation area (an area including not only the element region but also the element isolation regions). Consequently, a semiconductor device that has a small chip size and can be realized at a low cost can be provided.

Further, the semiconductor device of the embodiment includes the element isolation regions E1 provided only on the periphery (both sides) of one element region E2. Thus the device has the element region E2 and the element isolation regions E1 as small as possible in number so as to have a small occupation area. Accordingly, a semiconductor device that has a small chip size and can be realized at a low cost can be provided.

Further, in the case of the semiconductor device of the embodiment, the DMOS transistor 1 and the zener diode 2 can be easily formed on P-type diffusion regions (the first P-type diffusion region and the second P-type diffusion region) having different concentrations to each other (or may have the same concentration) only by using an element forming technique with respect to the P-type semiconductor substrate 10 including the epitaxial layer 11 that is common. Thus such semiconductor device can be provided that has a simple structure and includes the N-type DMOS transistor 1 and the protection element having a gate electrode film protection function in one element region E2.

Here, in the semiconductor device of the embodiment, the P-type semiconductor substrate 10 having the epitaxial layer 11 on its surface is used as one semiconductor substrate. However, the one semiconductor substrate may be a P-type semiconductor substrate having a triple well structure in which a P-well region is formed in an N-well region without the epitaxial layer 11. The P-well region includes a first P-type well region for forming the DMOS transistor 1 and a second P-type well region for forming the zener diode 2 serving as the protection element. The first P-type well region and the second P-type well region may be formed as diffusion regions that are separately formed. In this case, an On-resistance value of the DMOS transistor 1 is increased in some degree. However, the device does not have the N-type embedded region BN(N+), the N-type embedded region N(PLG), the P-type embedded region BP, and the P-type embedded region P(PLG), being able to further decrease the one chip size.

### First Modification

In a first modification, a pattern of the electrode formed in the second P-type diffusion region of the above embodiment is changed, and an NPN junction type transistor is formed instead of the zener diode 2 serving as the protection element shown in the above embodiment.

FIG. 3 illustrates an equivalent circuit of elements of a semiconductor device of this case. Referring to FIG. 3, the elements of this semiconductor device have a circuit structure in which a base electrode of the NPN junction type transistor 3 is coupled to the source electrode of the N-type DMOS transistor 1, and an emitter electrode of the NPN junction type transistor 3 is coupled to the gate electrode. Here, a collector electrode of the NPN junction type transistor 3 is coupled to the drain electrode of the DMOS transistor 1 and short-circuited, so that the NPN junction type transistor 3 functions as the case of the zener diode 2 of the above embodiment.

In such the structure, the DMOS transistor 1 and the NPN junction type transistor 3 can be easily formed on P-type diffusion regions (the first P-type diffusion region and the second P-type diffusion region) having different concentrations to each other only by using an element forming technique with respect to the P-type semiconductor substrate 10 including the epitaxial layer 11 that is common, as is the case with the above embodiment. Thus such different type semiconductor device can be provided that has a simple structure and includes the N-type DMOS transistor 1 and the protection element having a gate electrode film protection function in one element region E2.

This case also can employ a P-type semiconductor substrate having a triple well structure in which a P-well region is formed in an N-well region. The P-well region includes a first P-type well region for forming the DMOS transistor 1 and a second P-type well region for forming the NPN junction type transistor 3 serving as the protection element. The first P-type well region and the second P-type well region may be formed as the diffusion regions that are separately formed.

### Second Modification

A plurality of element integrated structures, in which the zener diode 2 or the NPN junction type transistor 3 coupled to the gate electrode and the source electrode in the drain electrode region of the N-type DMOS transistor 1, are arranged in a predetermined number and element-isolated from each other in a manner to couple drain electrodes of the element integrated structures that are adjacent to each other and to couple source electrodes of those. Here, in such a multiple structure, drain electrodes of the DMOS transistors 1 are coupled to each other, and source electrodes of the DMOS transistors 1 are also coupled to each other.

Thus, a semiconductor device has a multiple structure in which the element integrated structures are arranged side by side, and the element integrated structures are isolated from each other by the element isolation regions E1 disposed to sandwich one element region E2. In the integrated structure, the N-type DMOS transistor 1 and the protection element having a gate electrode protection function are formed. Therefore, the device has a substantially smaller size than a device having an element isolation structure of a related art, and a high-effective gate electrode protection function can be obtained. Especially, in a case where the device is applied as a switching element such as an H-bridge type circuit for driving a motor, the device does not need a large disposing space due to its one chip structure having a substantially smaller size than the related art. Further, surge voltage applied to the gate electrode is absorbed, that is, no surge voltage is applied to the gate electrode, so that the device is securely protected. Thus such device is substantially effective.

What is claimed is:

1. A semiconductor device, comprising:
a double-diffused metal oxide semiconductor (DMOS) transistor having a gate electrode and a drain electrode region; and
a protection element protecting the gate electrode with respect to overvoltage and coupled to the DMOS transistor on a structure of one semiconductor substrate,
the DMOS transistor and the protection element being included in an element integrated structure, wherein
the protection element is formed on a diffusion region, the diffusion region being separately formed with respect to a diffusion region for the DMOS transistor, in a drain electrode region of the DMOS transistor.

2. The semiconductor device according to claim 1,
wherein the one semiconductor substrate is a P-type substrate having an epitaxial layer on a surface thereof,
wherein the diffusion regions that are separately formed are P-type diffusion regions that are disposed in an N-type region of the epitaxial layer, the N-type region being formed by being surrounded by: a first N-type embedded region,
the first N-type embedded region being embedded at a boundary part between the epitaxial layer and the P-type substrate; second N-type embedded regions,
the second N-type embedded regions being embedded on end parts of the first N-type embedded region at the boundary part with a predetermined distance from each other; and N-type diffusion regions, the N-type diffusion regions being formed on the second N-type embedded regions in a manner exposing surfaces thereof from the epitaxial layer, and
wherein the P-type diffusion regions are a first P-type diffusion region on which the DMOS transistor is formed and a second P-type diffusion region on which the protection element is formed at a distance from the first P-type diffusion region.

3. The semiconductor device according to claim 2, wherein the drain electrode region of the DMOS transistor that is N-type DMOS transistor is element-isolated by: first P-type embedded regions, the first P-type embedded regions being embedded at the boundary part between the epitaxial layer and the P-type substrate in a manner sandwiching the first N-type embedded region;
second P-type embedded regions, the second P-type embedded regions being embedded on the first P-type embedded regions; and P-type diffusion regions,
the P-type diffusion regions being formed on the second P-type embedded regions in a manner exposing surfaces thereof from the epitaxial layer.

4. The semiconductor device according to claim 1,
wherein the one semiconductor substrate is a P-type substrate having a triple well structure in which a P-well region is formed in an N-well region, and the P-well region includes a first P-type well region for forming the DMOS transistor and a second P-type well region for forming the protection element, and
wherein the diffusion regions that are separately formed are the first P-type well region and the second P-type well region.

5. The semiconductor device according to claim 1,
wherein the DMOS transistor is an N-type DMOS transistor, and
wherein the protection element is a zener diode of which an anode electrode is coupled to a source electrode of the N-type DMOS transistor and a cathode electrode is coupled to the gate electrode of the N-type DMOS transistor.

6. The semiconductor device according to claim 1,
wherein the DMOS transistor is an N-type DMOS transistor, and
wherein the protection element is an NPN junction type transistor of which a base electrode is coupled to a source electrode of the N-type DMOS transistor and an emitter electrode is coupled to the gate electrode of the N-type DMOS transistor.

7. The semiconductor device according to claim 5, wherein the element integrated structure is arranged side by side in a predetermined number, and the predetermined number of element integrated structures include one of the zener diode or the NPN junction type transistor coupled to the gate electrode and the source electrode of the N-type DMOS transistor in the drain electrode region of the N-type DMOS transistor, and are element-isolated from each other in a manner coupling drain electrodes of the element integrated structures that are adjacent to each other and coupling source electrodes of the element integrated structures that are adjacent to each other.
